(19) United States
(12) Patent Application Publication
(10) Pub. No.: US 2007/0181923 A1
(43) Pub. Date: Aug. 9, 2007

(54) SOLID-STATE IMAGE SENSOR COMPRISING PLURAL LENSES

(76) Inventor: Nagataka TANAKA, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/670,513

(22) Filed: Feb. 2, 2007

(30) Foreign Application Priority Data
Feb. 3, 2006 (JP) 2006-027201

(51) Int. Cl. H01L 31/062

(52) U.S. Cl. 257/294; 257/E27.133

(57) ABSTRACT

A solid-state image sensor includes pixels and lenses. Each of the pixels on a semiconductor substrate includes a photodetecting section which photoelectrically converts incident light. Each of the lenses condenses the incident light on the photodetecting section. The lenses have a fixed curvature on an incident surface for the incident light. A top of the incident surface of each of the lenses is at a position different from that of a center of a bottom surface of each of the lenses in a direction horizontal to the bottom surface.

### CROSS-REFERENCE TO RELATED APPLICATIONS

This application is based upon and claims the benefit of priority from prior Japanese Patent Application No. 2006-027201, filed Feb. 3, 2006, the entire contents of which are incorporated herein by reference.

### BACKGROUND OF THE INVENTION

1. Field of the Invention

The present invention relates to solid-state image sensor. In particular, the present invention relates to microlenses in solid-state image sensor which condense light incident on pixels.

2. Description of the Related Art

An effective method for reducing the sizes electronic cameras is to reduce the sizes of image areas and thus of optical systems. This requires the pixel size of CMOS sensors to be shrunk. To shrink the pixel size, attempts have been made to allow a plurality of photodiodes to share a transistor in each pixel to reduce the number of transistors per photodiode, as disclosed in Jpn. Pat. Appln. KOKAI Publication No. H10-150182.

The conventional CMOS sensor has microlenses that condense incident light and photodiodes that convert the incident light condensed by the microlenses into charges. For example, as described in Published Japanese Patent No. S60-59752, each of the microlenses normally has a laterally asymmetrical sectional shape. Accordingly, the focus of the microlens is located immediately below its top, that is, almost immediately below the center of bottom surface of the microlens.

However, in the above configuration, the microlenses are spaced at equal intervals, so that the foci are spaced at equal intervals. As a result, a gate of a MOS transistor adjacent to each photodiode blocks incident light. This reduces the photosensitivity of the CMOS area sensor.

### BRIEF SUMMARY OF THE INVENTION

A solid-state image sensor according to an aspect of the present invention includes:

pixels on a semiconductor substrate, each of the pixels including a photodetecting section which photoelectrically converts incident light; and

lenses which condense the incident light on the photodetecting section, the lenses having a fixed curvature on an incident surface for the incident light, a top of the incident surface of each of the lenses being at a position different from that of a center of a bottom surface of each of the lenses in a direction horizontal to the bottom surface.

### BRIEF DESCRIPTION OF THE SEVERAL VIEWS OF THE DRAWING

FIG. 1 is a sectional view of a solid-state image sensor in accordance with a first embodiment of the present invention;

FIG. 2 is a plan view of the solid-state image sensor in accordance with the first embodiment of the present invention;

FIG. 3 is a sectional view of a conventional solid-state image sensor;

FIG. 4 is a sectional view of a solid-state image sensor in accordance with a second embodiment of the present invention;

FIG. 5 is an enlarged view of a partial area of FIG. 4;

FIG. 6 is a plan view of the solid-state image sensor in accordance with the second embodiment of the present invention;

FIG. 7 is a block diagram of a solid-state image sensor in accordance with a third embodiment of the present invention;

FIG. 8 is a circuit diagram of a unit cell in the solid-state image sensor in accordance with the third embodiment of the present invention;

FIG. 9 is a plan view of the unit cell in the solid-state image sensor in accordance with the third embodiment of the present invention;

FIG. 10 is a sectional view taken along line 10-10 in FIG. 9;

FIG. 11 is a circuit diagram of a unit cell in a solid-state image sensor in accordance with a fourth embodiment of the present invention;

FIG. 12 is a plan view of a light receiving section of the solid-state image sensor in accordance with the fourth embodiment of the present invention;

FIG. 13 is a sectional view taken along line 13-13 in FIG. 12;

FIG. 14 is a plan view of a light receiving section of a solid-state image sensor in accordance with a fifth embodiment of the present invention;

FIG. 15 is a plan view of a light receiving section of a solid-state image sensor in accordance with a sixth embodiment of the present invention;

FIG. 16 is a sectional view of a conventional solid-state image sensor;

FIG. 17 is a sectional view of a light receiving section of a solid-state image sensor in accordance with a seventh embodiment of the present invention;

FIG. 18 is a sectional view of partial areas of the solid-state image sensor in accordance with the first to seventh embodiments of the present invention and of a conventional solid-state image sensor;

FIG. 19 is a perspective view of the solid-state image sensor in accordance with a variation of the first to seventh embodiments of the present invention;

FIG. 20 is a plan view of a photomask used for production of a microlens in the solid-state image sensor in accordance with the first to fifth and seventh embodiments of the present invention;

FIG. 21 is a sectional view of a first method for manufacturing the microlens in the solid-state image sensor in accordance with the first to fifth and seventh embodiments of the present invention;

FIG. 22 is a sectional view of a second method for manufacturing the microlens in the solid-state image sensor in accordance with the first to fifth and seventh embodiments of the present invention;

FIG. 23 is a plan view of the solid-state image sensor in accordance with a modification of the first to seventh embodiment of the present invention;

FIG. 24 is a sectional view taken along line 24-24 in FIG. 23; and

FIG. 25 is a plan view of the solid-state image sensor in accordance with a modification of the first to seventh embodiment of the present invention.

### DETAILED DESCRIPTION OF THE INVENTION

### First Embodiment

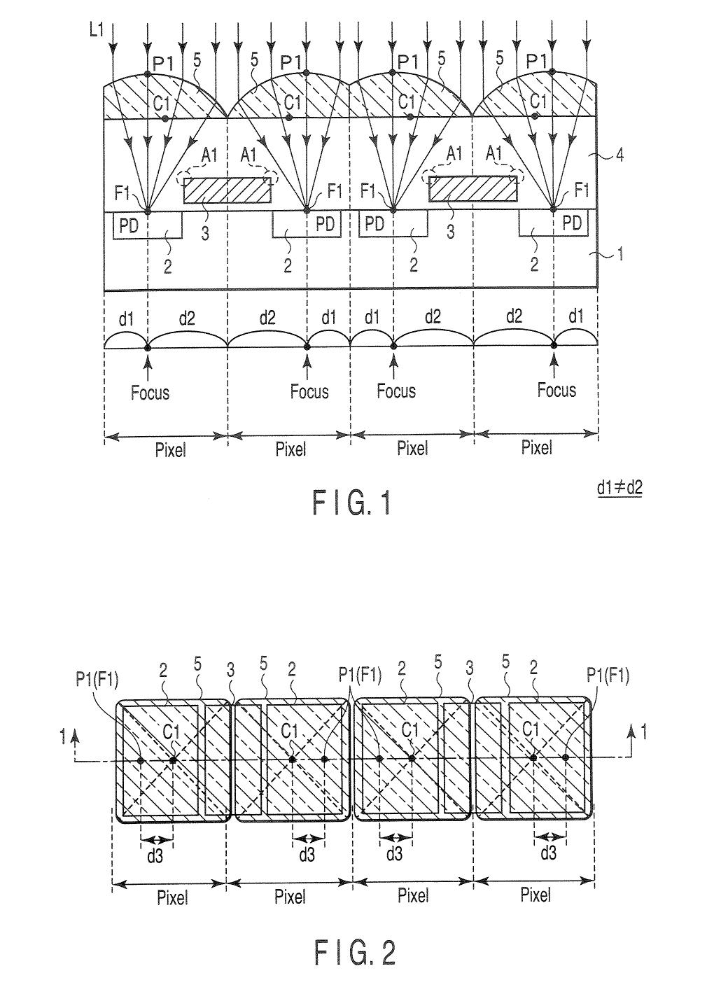

With reference to FIGS. 1 and 2, a solid-state image sensor in accordance with a first embodiment of the present invention will be described. FIGS. 1 and 2 are a sectional view and a plan view, respectively, of the solid-state image sensor in accordance with the present embodiment. In particular, these figures show the center of an image area in the solid-state image sensor. FIGS. 1 and 2 correspond to sectional views taken along line 1-1.

As shown in the figures, a plurality of photodetecting sections, for example, photodiodes 2 are provided in a surface of a semiconductor substrate 1. The photodiodes 2 are formed by using, for example, ion implantation to doping impurities of a conductivity type opposite to that of the semiconductor substrate 1, in its surface. Gate electrodes 3 are each provided on the semiconductor substrate 1 between adjacent photodiodes 2 with a gate insulating film interposed therebetween. An insulating film 4 is provided on the semiconductor substrate 1 so as to cover the photodiodes 2 and gate electrodes 3. Microlenses 5 are provided on the insulating film 4 in association with the respective photodiodes 2. In this configuration, a plurality of pixels are formed each of which includes one photodiode.

The top P1 of the microlens 5 in accordance with the present embodiment is at a distance d1 from one end of the microlens 5 and at a distance d2 (≠d1) from the other end of the microlens 5. Accordingly, the position of the top P1 is different from that of center C1 of a bottom surface of the microlens 5 in a direction horizontal to the bottom surface. In other words, the top P1 of the microlens 5, that is, its focus F1, is present at a distance d3 from a perpendicular to the bottom surface of the microlens 5 which contains the center C1 (see FIG. 2). In other words, as shown in FIG. 1, the microlens 5 has a laterally asymmetrical sectional shape. The top P1 is defined as a position on the microlens 5 where it has the largest film thickness. The microlens 5 has a uniform curvature on an incident surface on which incident light L1 impinges. The curvature is set so that the focus F1 lies on a surface of the photodiode 2.

The top P1 of the microlens 5 lies opposite the gate electrode 3 across the center C1 of the microlens 5 in a direction in which the photodiode 2 and gate electrode 3 are arranged. That is, the top P1 of the microlens 5 is disposed at its end (second end) far from the gate electrode 3 in the direction in which the photodiode 2 and gate electrode 3 are arranged; the first end of the microlens 5 is near the gate electrode 3. In other words, in FIG. 2, the top P1 is disposed so that P1, C1, and the gate electrode 3 are arranged in this order along the direction in which the photodiode 2 and gate electrode 3 are arranged.

In this configuration, upon reaching the microlens 5, the incident light Ll is refracted in accordance with Snell's law. The refracted incident light L1 forms an image on the photodiode 2 corresponding to the microlens 5. The photodiode 2 photoelectrically converts the incident light L1 into charges.

This configuration exerts the following effect.

(1) A decrease in the photosensitivity of the solid-state image sensor can be inhibited (1).

In the configuration in accordance with the present embodiment, the top of the microlens is away from the center of its bottom surface in the direction horizontal to the bottom surface of the microlens, which condenses incident light on the photodiode. This enables a decrease in the photosensitivity of the solid-state image sensor to be inhibited. This effect will be described below in detail.

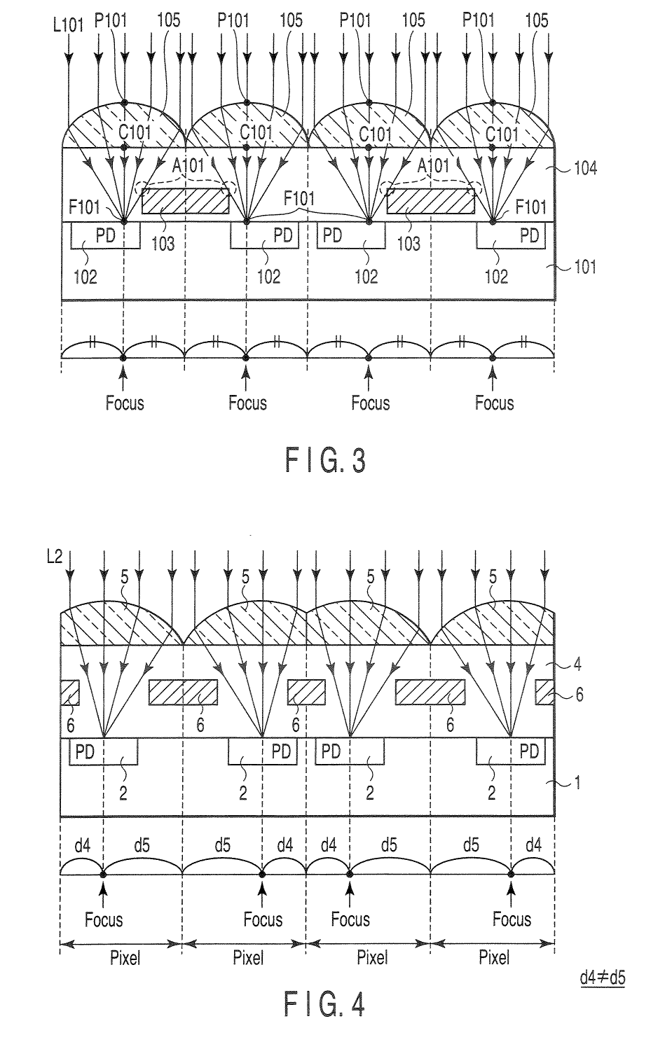

FIG. 3 is a sectional view of a conventional solid-state image sensor. As shown in the figure, photodiodes 102 are provided in a surface of a semiconductor substrate 101. Gate electrodes 103 are each provided on the semiconductor substrate 101 between adjacent photodiodes 102. An insulating film 104 is provided on the semiconductor substrate 101 so as to cover the photodiodes 102 and gate electrodes 103. Microlenses 105 are provided on the insulating film 104. Each of the microlenses 105 has a cross section laterally symmetrical with respect to a top P101. That is, the top P101 of the microlens 105 is at an equal distance from the opposite ends the microlens 105 in the direction in which the photodiode 102 and gate electrode 103 are arranged. Accordingly, the top P101 of the microlens 105, the center C101 of the bottom surface of the microlens 105, and the focus F101 of the microlens 105 are all located on a perpendicular to the surface of the photodiode 102.

Thus, since the microlens 105 are spaced at equal intervals, the foci F101 are spaced at equal intervals. On the other hand, the photodiodes 102 are not spaced at equal intervals; a larger interval corresponds to the area between the photodiodes 102 in which the gate electrode 103 is sandwiched between the photodiodes 102, and a smaller interval corresponds to the area between the photodiodes 102 in which the gate electrode 103 is not present. As a result, the incident light L101 condensed by the microlens 105 is partly blocked by the gate electrode 103 (in FIG. 3, an area A101). This undesirably reduces the photosensitivity of the solid-state image sensor.

In contrast, in the configuration in accordance with the present embodiment, the top P1 of the microlens 5 is away from the center C1 of bottom surface of the microlens 5 in the direction horizontal to the bottom surface of the microlens 5 (that is, horizontal to the surface of the photodiode 2). Consequently, the microlenses 5 are spaced at equal intervals but the foci of the microlenses 5 are not. More specifically, as described with reference to FIG. 2, the top P1 of the microlens 5 is disposed at its end (second end) far from the gate electrode 3 in the direction in which the photodiode 2 and gate electrode 3 are arranged; the first end of the microlens 5 is near the gate electrode 3. Thus, the incident light L1 condensed by the microlens 5 enters the photodiode 2 so as to be kept away from a corner of the gate electrode 3 (the area A1 in FIG. 1). Further, even if the incident light L1 is blocked, the quantity of light blocked is smaller than in the conventional art. This allows more light to enter the photodiode 2 to inhibit a decrease in the photosensitivity of the solid-state image sensor.

### Second Embodiment

Now, with reference to FIG. 4, a solid-state image sensor in accordance with a second embodiment of the present invention will be described. FIG. 4 is a sectional view of the solid-state image sensor in accordance with the present embodiment. The present embodiment is the same as the first embodiment except for a metal wiring layer in the insulating film 4.

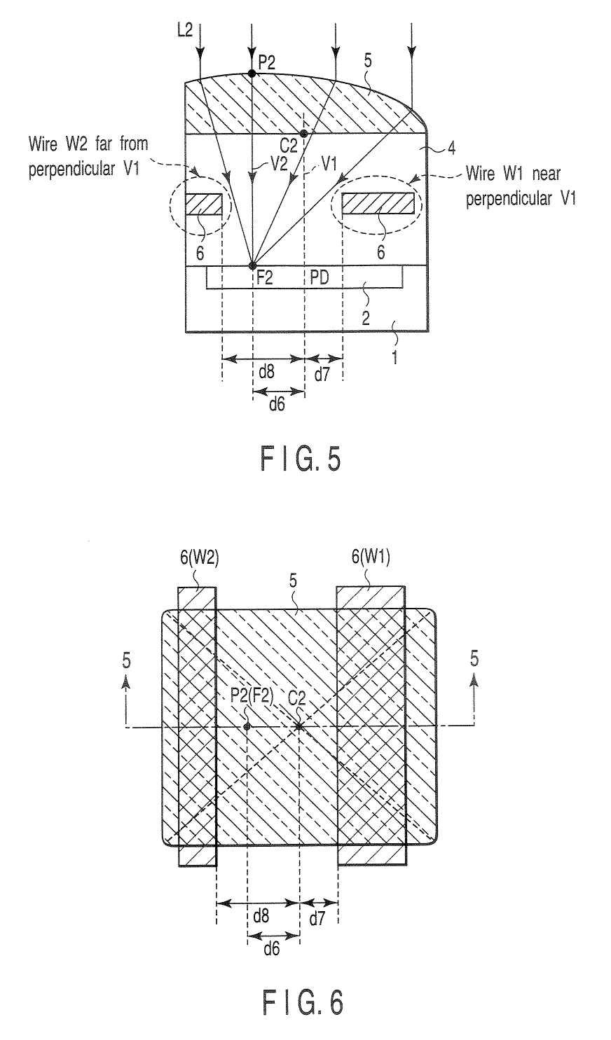

As shown in the figure, the solid-state image sensor in accordance with the present embodiment has the configuration described in the first embodiment with reference to FIG. 1 and further comprises plural metal wiring layers 6 in the insulating film 4. The metal wiring layers 6 are formed to extend perpendicularly to the sheet of the drawing. In FIG. 4, the illustration of the gate electrodes 3 is omitted. The top P2 of the microlens 5 in accordance with the present embodiment is at a distance d4 from one end of the microlens 5 and at a distance d5 (>d4) from the other end of the microlens 5. FIGS. 5 and 6 are enlarged views of one of the pixels in FIG. 4 and show a sectional structure and a planar structure. FIG. 5 corresponds to a cross section taken along line 5-5 in FIG. 6.

As shown in FIGS. 5 and 6, the top P2 of the microlens 5, that is, its focus F2, is a distance d6 away from a perpendicular V1 to the bottom surface of the microlens 5 which contains the center C2 of the bottom surface, in the direction horizontal to the bottom surface of the microlens 5. That is, as in the case of the first embodiment, the microlens 5 has a laterally asymmetrical sectional shape. Of course, the microlens 5 has a uniform curvature on the incident surface on which incident light L2 impinges.

The distances between the perpendicular V1 and the two metal wiring layers 6 located across the perpendicular V1 are defined as d7 and d8 (d7<d8). One of the metal wiring layers 6 which is near the perpendicular V1 is called a wire W1. The metal wiring layer 6 far from the perpendicular V1 is called a wire W2. Then, the top P2 of the microlens 5 lies opposite the wire W1 across the perpendicular V1. In other words, a straight line V2 joining the top P2 of the microlens 5 and the focus F2 together is located between the wire W2 and the perpendicular V1.

This configuration exerts the following effect.

(2) A decrease in the photosensitivity of the solid-state image sensor can be inhibited (2).

In the configuration in accordance with the present embodiment, the top P2 of the microlens 5 is away from the center C2 of bottom surface of the microlens 5 in the direction horizontal to the bottom surface of the microlens 5 as in the case of the first embodiment. Consequently, the microlenses 5 are spaced at equal intervals but the foci of the microlenses 5 are not. More specifically, as described with reference to FIGS. 5 and 6, the top P2 of the microlens 5 is disposed in proximity to one of the two metal wiring layers 6 between which the perpendicular V1, passing through the center of the pixel, is sandwiched, that is, the wire W2 far from the perpendicular V1. Thus, the incident light L2 condensed by the microlens 5 enters the photodiode 2 so as to be kept away from corners of the metal wiring layers 6, particularly a corner of the wire W1. Further, even if the incident light L2 is blocked, the quantity of light blocked is smaller than in the conventional art. This allows more light to enter the photodiode 2 to inhibit a decrease in the photosensitivity of the solid-state image sensor.

That is, the present embodiment exerts an effect similar to that of the first embodiment to prevent the incident light L2 from being blocked by the metal wiring layers 6. However, the metal wiring layers 6 are normally located at a higher level than the gate electrodes, described in the first embodiment, that is, located closer to the microlenses 5. Consequently, the metal wiring layers 6 are more likely to block the incident light L2 than the gate electrodes. Therefore, the use of the microlens 5 in accordance with the present embodiment is more effective than that in the first embodiment.

### Third Embodiment

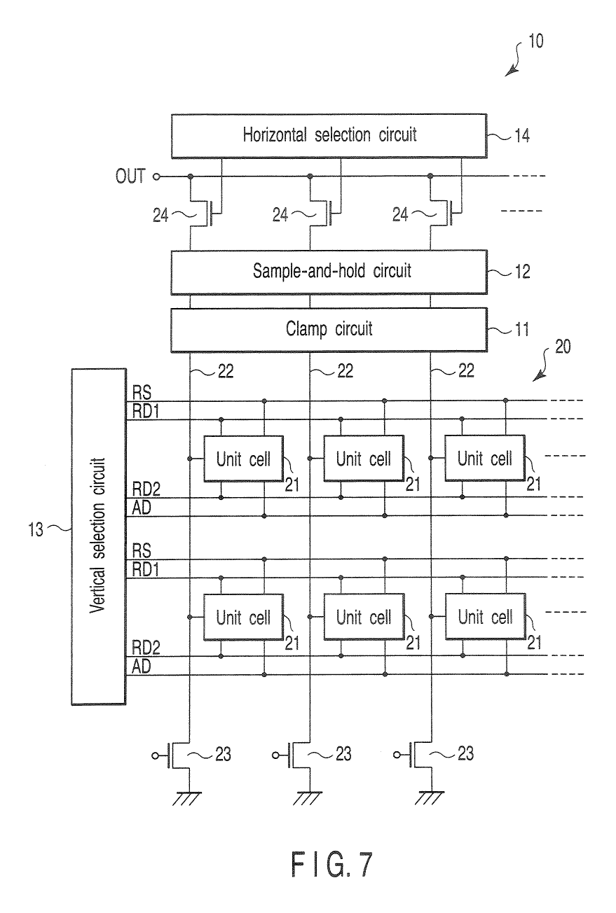

Now, a solid-state image sensor in accordance with a third embodiment of the present invention will be described. The present embodiment relates to a solid-state image sensor which includes the microlens 5 described in the first and second embodiments and in which an amplifying transistor is shared by two photodiodes. FIG. 7 is a block diagram of the solid-state image sensor.

As shown in the figure, the solid-state image sensor 10 comprises a clamp circuit 11, a sample-and-hold circuit 12, vertical selection circuit 13, a horizontal selection circuit 14, and a light receiving section 20.

The light receiving section 20 comprises a plurality of unit cells 21 which photoelectrically convert incident light. FIG. 7 shows only (2×3) unit cells 21. However, the number of unit cells 21 is not particularly limited. The plurality of unit cells 21 are arranged in a matrix. Vertical signal lines 22 are connected to respective columns of unit cells. The unit cells 21 in the same row are connected to the same address signal line AD, the same reset signal line RS, and the same read signal lines RD1 and RD2. The vertical selection circuit 13 selects any of the address signal lines AD, reset signal lines RS, and read signal lines RD1 and RD2.

The clamp circuit 11 is connected to one end of each of the vertical signal lines 22 to clamp a signal read onto the vertical signal line 22. The other end of the vertical signal line 22 is connected to a ground potential via a load transistor 23.

The sample-and-hold circuit 12 samples and holds a signal clamped by the clamp circuit 11. The signal held by the sample-and-hold circuit 12 is output to an output node OUT via a read transistor 24. A gate of the read transistor 24 is controlled by the horizontal selection circuit 14.

Now, the configuration of the unit cell 21 will be described with reference to FIG. 8. FIG. 8 is a circuit diagram of one of the unit cells 21 in FIG. 7. As shown in FIG. 8, the unit cell 21 comprises two pixels 25, 25 and one signal output section 26. The signal output section 27 is shared by the two pixels 25, 25.

Each of the pixels 25 comprises a read transistor 28 and a photodiode 29. Gates of the two read transistors 28 included in the same unit cell 21 are connected to the read signal lines RD1 and RD2, respectively. A drain of each read transistor 28 is connected to an anode of the photodiode 29 in the corresponding pixel 25. A cathode of the photodiode 29 is grounded.

The signal output section 26 comprises an amplifying transistor 30, an address transistor 31, and a reset transistor 32. The amplifying transistor 30 has a gate connected to sources of the transistors 28 in both pixels 25, a source connected to the vertical signal line 22, and a drain connected to a source of the transistor 31. The address transistor 31 has a gate connected to the address signal line AD and a drain connected to a power supply potential VDD. The reset transistor 32 has a gate connected to the reset signal line RS, a source connected to the sources of the transistors 28 in both pixels 25, and a drain connected to the power supply potential VDD. That is, the one signal output section 26 is shared by the two pixels 25.

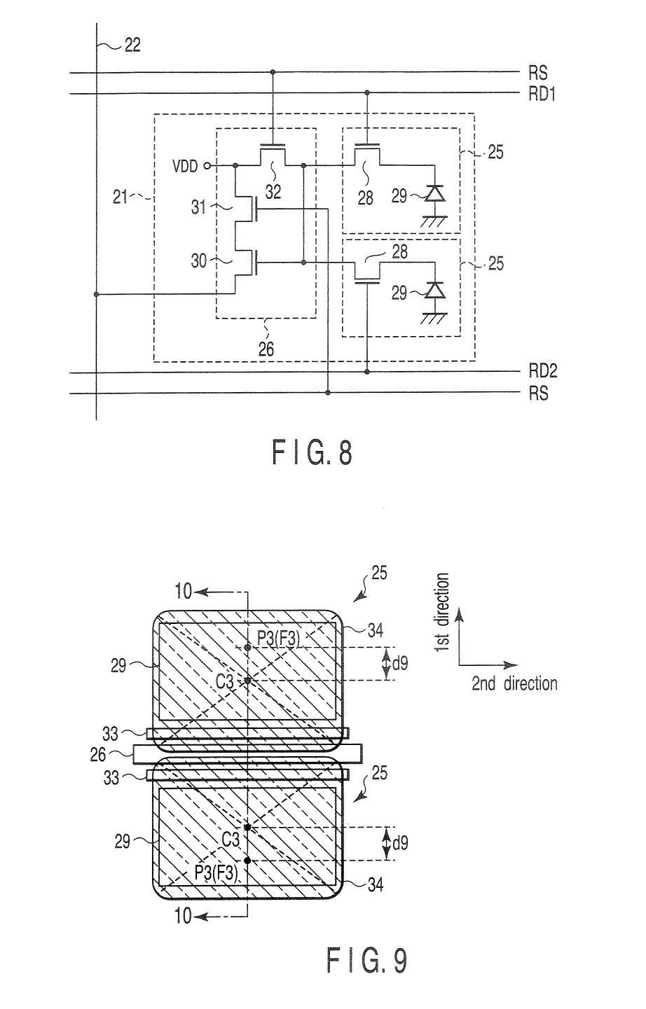

FIG. 9 is a plan view of the unit cell 21 shown in FIG. 8. As shown in FIG. 9, the two photodiodes 29 are located along a first direction. The transistors 28 are provided between the two photodiodes 29 so as to sandwich the signal output section 26 between the transistors 28 along the first direction. Gates 33 of the transistors 28 are formed along a second direction orthogonal to the first direction. In FIG. 9, the detailed illustration of the signal output section 26 is omitted.

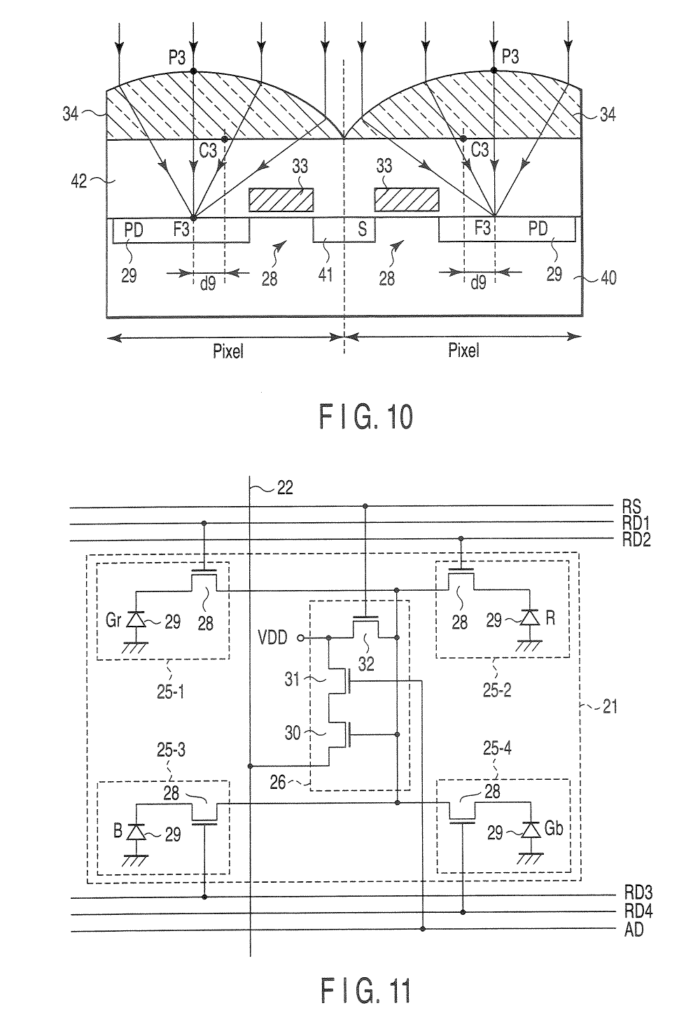

FIG. 10 is a sectional view taken along line 10-10 in FIG. 9. The sectional configuration is almost similar to that in the first embodiment. Specifically, as shown in FIG. 10, a plurality of photodiodes 29 are provided in a surface of a semiconductor substrate 40. The gate electrodes 33 of the two transistors 28 are each provided on the semiconductor substrate 40 between the adjacent photodiodes with a gate insulating film interposed therebetween. Source areas 41 of the two transistors 28 are formed in the semiconductor substrate 40 between the adjacent gate electrodes 33. In FIG. 10, the illustration of the signal output section 26 is omitted. An insulating film 42 is provided on the semiconductor substrate 40 so as to cover the photodiodes 29 and gate electrodes 28. Microlenses 34 are provided on the insulating film 42 in association with the pixels 25. Accordingly, each unit cell 21 includes two microlenses 34.

For the microlens 34 in the solid-state image sensor in accordance with the present embodiment, the relationship between its top P3 (focus F3) and the center C3 of its bottom surface is similar to that in the first embodiment. That is, the top P3 of the microlens 34, that is, its focus F3, is a distance d9 away from a perpendicular containing the center C3 of the bottom surface of the microlens so as to away from the gate electrode 33. In other words, as shown in FIG. 10, the microlens 5 has a laterally asymmetrical sectional shape.

Now, operations of the solid-state image sensor configured as described above will be described. First, in the light receiving section 20, any of the unit cells 21 is selected. In this selecting operation, an address signal AD output by the vertical selection circuit 13 turns on the address transistor 31 in any of the unit cells 21. Further, the load transistor 23 connected to the corresponding vertical signal line 22 is turned on.

Further, a reset operation is performed to set the vertical signal line 22 to a given reference potential. In the reset operation, the vertical selection circuit 13 asserts a reset signal RS to turn on the reset transistor 32 in the selected unit pixel. Turning on the reset transistor 32 provides VDD to the gate of the amplifying transistor 30 via a current path in the transistor 32 to turn on the transistor 30. Then, since the address transistor 31 is on, the vertical signal line 22 is set to the given reference potential through a path extending from the power supply potential VDD to the vertical signal line 22 via the current path in the transistors 31 and 30.

The vertical selection circuit 13 then selects one of the read signal lines RD1 and RD2. The read transistor 28 connected to the selected read signal line RD1 or RD2 is then turned on. Consequently, in the pixel 25 with the transistor 28 turned on, charges generated in the photodiode 29 in response to incident light reach the gate of the amplifying transistor 30 via the current path in the transistor 28. This varies the potential of the vertical signal line 22 depending on the result of photoelectric conversion in the photodiode 29. Specifically, an image signal is provided to the vertical signal line 22 on the basis of the charges from the photodiode 29. The image signal is read onto an output node OUT via the clamp circuit 11, sample-and-hold circuit 12, and read transistor 24.

As described above, the solid-state image sensor in accordance with the present embodiment exerts the effect (1), described in the first embodiment. The effect (1) is particularly significant when the signal output section 26 is shared by a plurality of pixels as in the present embodiment. As shown in FIGS. 9 and 10, when the signal output section 26 is shared by the two pixels 25, the transistor 28 and signal output section 29 are arranged between the two pixels 25.

Consequently, the shape of each pixel 25 is laterally asymmetrical in the direction shown in FIG. 10. In this pattern, the gate electrode 33 is located at one end of the pixel 25. Therefore, the position of center of the pixel 25 (that is, the center of the microlens 5) is different from that of center of the photodiode 29. Incident light is thus likely to be blocked by the gate electrode 33.

However, in the present embodiment, the top P3 of the microlens 34, which condenses incident light on the photodiode 29, is away from the center C3 of the bottom surface of the microlens 34 in the direction horizontal to the bottom surface of the microlens 34. This prevents the incident light from being blocked by the gate electrode. Thus, a decrease in the photosensitivity of the solid-state image sensor can be inhibited as described in the first embodiment.

### Fourth Embodiment

Now, a solid-state image sensor in accordance with a fourth embodiment of the present invention will be described. The present embodiment is the same as the third embodiment except that each unit cell 21 includes four pixels 25 and that the light receiving section 20 includes read signal lines RD3 and RD4 in addition to the read signal lines RD1 and RD2. The vertical selection circuit selects any of the read signal lines RD1 to RD4. FIG. 11 is a circuit diagram of the unit cell 21 in the solid-state image sensor in accordance with the present embodiment.

As shown in FIG. 11, the unit cell 21 comprises four pixels 25-1 to 25-4 and one signal output section 26. The pixels 25-1 to 25-4 and signal output section 26 are configured as described in the third embodiment. The signal output section 26 is shared by the four pixels 25-1 to 25-4. Accordingly, the sources of the read transistors 28 included in the four pixels 25-1 to 25-4 are all connected to the gate of the amplifying transistor 30 and the source of the reset transistor 32, both of which are included in the signal output section 26. The gates of the read transistors 28 included in the four pixels 25-1 to 25-4 are connected to read signal lines RD1 to RD4, respectively. The vertical selection circuit 13 selects any of the read signal lines RD1 to RD4 as in the case of the address lines AD and reset signal lines RS. In this configuration, the pixels 25-1 to 25-4 comprise color filters (not shown) that detect green (Gr), red (R), blue (B), and green (Gb), respectively.

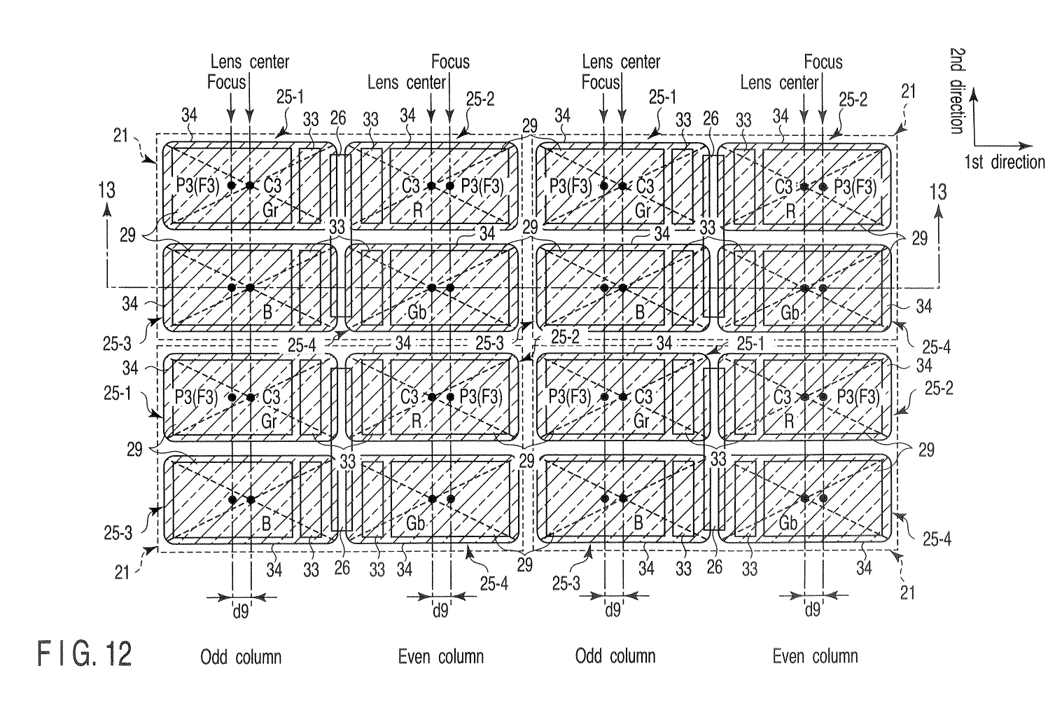

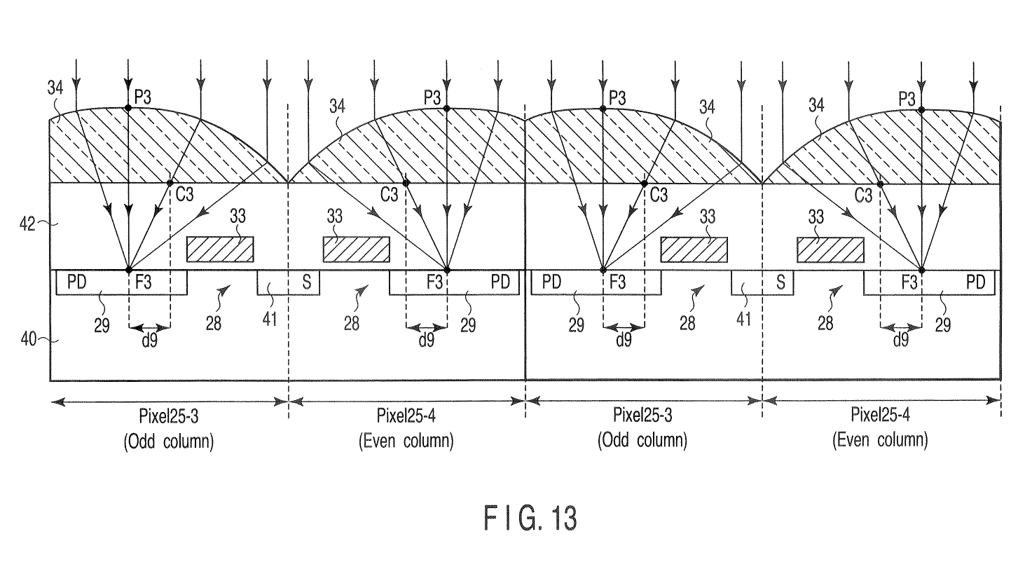

FIG. 12 is a plan view of the four unit cells 21 in accordance with the present embodiment. FIG. 13 is a sectional view taken along line 13-13 in FIG. 12. As shown in the figures, each unit cell 21 has the four pixels 25-1 to 25-4 arranged in a (2×2) matrix. In the light receiving section 20, the pixels 25-1 and 25-3 are arranged in odd columns, while the pixels 25-2 and 25-4 are arranged in even columns. In the pixels 25-1 and 25-2 in the same unit cell 21 which are adjacent to each other in the first direction and in the pixels 25-3 and 25-4 in the same unit cell 21 which are adjacent to each other in the first direction, the read transistors 28 are arranged in proximity to each other. In each unit cell 21, the signal output section 26 is placed in the area between the pixel columns. The microlens 34, described in the third embodiment, is provided for each of the pixels 25-1 to 25-4. As described in the third embodiment, the straight line joining the top P3 and focus F3 of the microlens 34 is located the distance d9 away from the center C3 of bottom surface of the microlens 34.

In the light receiving section 20 of the solid-state image sensor configured as described above, the photodiodes 29 in the pixels 25-1 and 25-3 in the odd columns are isolated from the corresponding signal output section 26 in the respective pixels 25-1 and 25-3, and the photodiodes 29 in the pixels 25-2 and 25-4 in the even columns are isolated from the corresponding signal output section 26 in the respective pixels 25-2 and 25-4. The top P3 of the microlens 34 corresponding to each pixel is placed opposite the adjacent pixel across the center C3 along the first direction. Accordingly, in the example in FIG. 12, in the light receiving section 20, the tops P3 of the microlenses 34 corresponding to the pixels 25-1 to 25-3 are located to the right of the center C3 and in the same column along the second direction. The tops P3 of the microlenses 34 corresponding to the pixels 25-2 to 25-4 are located to the left of the center C3 and in the same column along the second direction.

The above solid-state image sensor also exerts the effect (1), described in the first and third embodiments.

### Fifth Embodiment

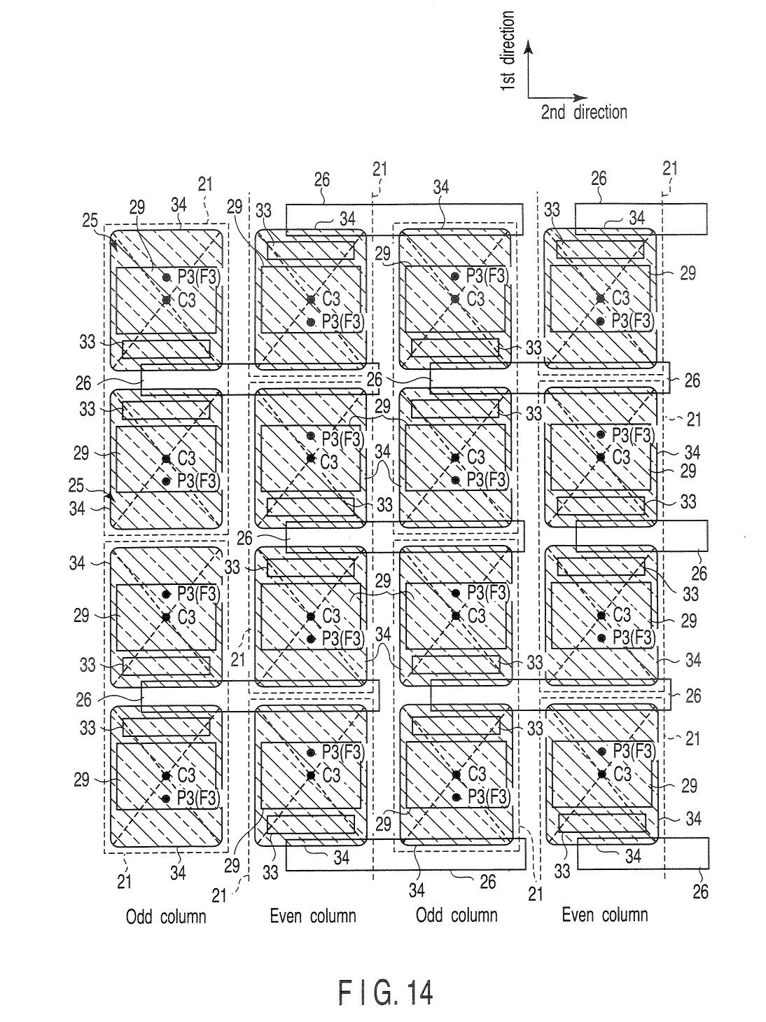

Now, a solid-state image sensor in accordance with a fifth embodiment of the present invention will be described. In the present embodiment, the microlens 5, described in the first and second embodiments, is applied to Jpn. Pat. Appln. KOKAI Publication No. 2006-302970. FIG. 14 is a plan view of a light receiving section in the solid-state image sensor.

The solid-state image sensor in accordance with the present embodiment is the same as the configuration described in the third embodiment with reference to FIGS. 7 and 9 except for the position of the gate 33 of the read transistor 28. FIG. 14 is a plan view of light receiving section 20 of the solid-state image sensor in accordance with the present embodiment. As shown in the figure, the light receiving section 20 has a plurality of pixels 25 arranged in a matrix.

As shown in the figure, the unit cell 21 has a configuration similar to that described in the third embodiment with reference to FIG. 9. The unit cell 21 includes two pixels 25 adjacent to each other in the first direction. The plurality of pixels 25 in the light receiving section 20 are arranged in a checkered pattern so that each unit cell 21 in each odd column is offset from the corresponding unit cell 21 in the adjacent even column by one pixel. The signal output section 26 in one unit cell 21 extends from a region between the two pixels 25 in this unit cell 21 over another region between other unit cells, the other unit cells being adjacent the one unit cell 21 in the second direction.

That is, in FIG. 14, in the pixel 25 adjacent to the pixel 25 located in one odd row and having the gate 33 below the photodiode 29, the gate 33 is located above the photodiode 29 in the figure. In contrast, in the pixel 25 adjacent to the pixel 25 located in one odd row and having the gate 33 above the photodiode 29, the gate 33 is located below the photodiode 29 in the figure.

In other words, the unit cells 21 each include two pixels 25 adjacent to each other in the first direction (vertical direction) and are arranged in a checkered pattern within the light receiving section 20. The signal output section 26 extends from between the two pixels 25 in the same unit cell 21 over the adjacent unit cell 21 in the second direction (horizontal direction). Moreover, the photodiodes 29 included in one of the pixels 25 in one unit cell 21 and in the diagonally adjacent unit cell 21 are arranged along the same horizontal line.

This configuration can also use the microlens 34, described in the third embodiment. The gates 33 of the pixels 25 adjacent to each other in the second direction are arranged opposite each other in the first direction across the center of the pixels 25. Consequently, between the two pixels 25 adjacent to each other in the second direction, the position of top P3 of the microlens 34, that is, its focus F3, in one of the pixels 25 is opposite to that in the adjacent pixel in the first direction. The configuration in accordance with the present embodiment also exerts the effect (1), described in the first and third embodiments.

### Sixth Embodiment

Now, a solid-state image sensor in accordance with a sixth embodiment of the present invention will be described. The present embodiment varies the curvature of the microlens depending on its position in the light receiving section to improve the photosensitivity of the solid-state image sensor.

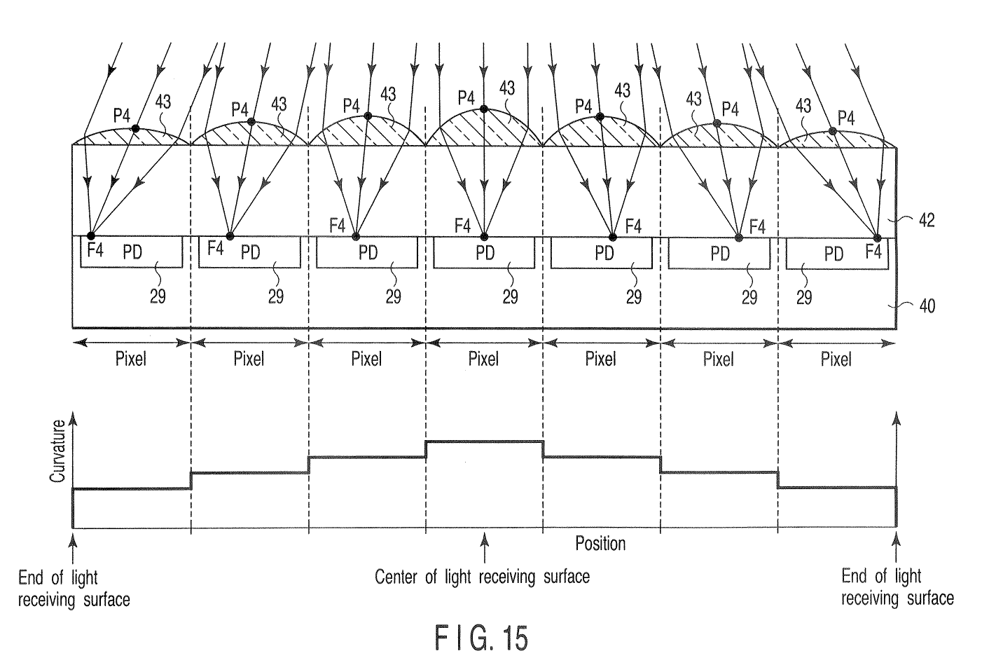

The solid-state image sensor is configured as described in the first embodiment with reference to FIG. 7. FIG. 15 shows the sectional configuration of the light receiving section 20 and the curvature of the microlens. As shown in FIG. 15, the microlens 43 is provided, for each pixel, above the photodiode 29 with the insulating film 42 interposed therebetween. The light incident surfaces of the microlenses 43 have different fixed curvatures. Further, the curvature of each microlens is largest in the center of the light receiving section 20 and decreases toward the ends. In FIG. 15, for simplification, the illustration of the gate electrodes 33 is omitted.

The present configuration exerts the following effect.

(3) A decrease in the photosensitivity of the solid-state image sensor can be inhibited (3).

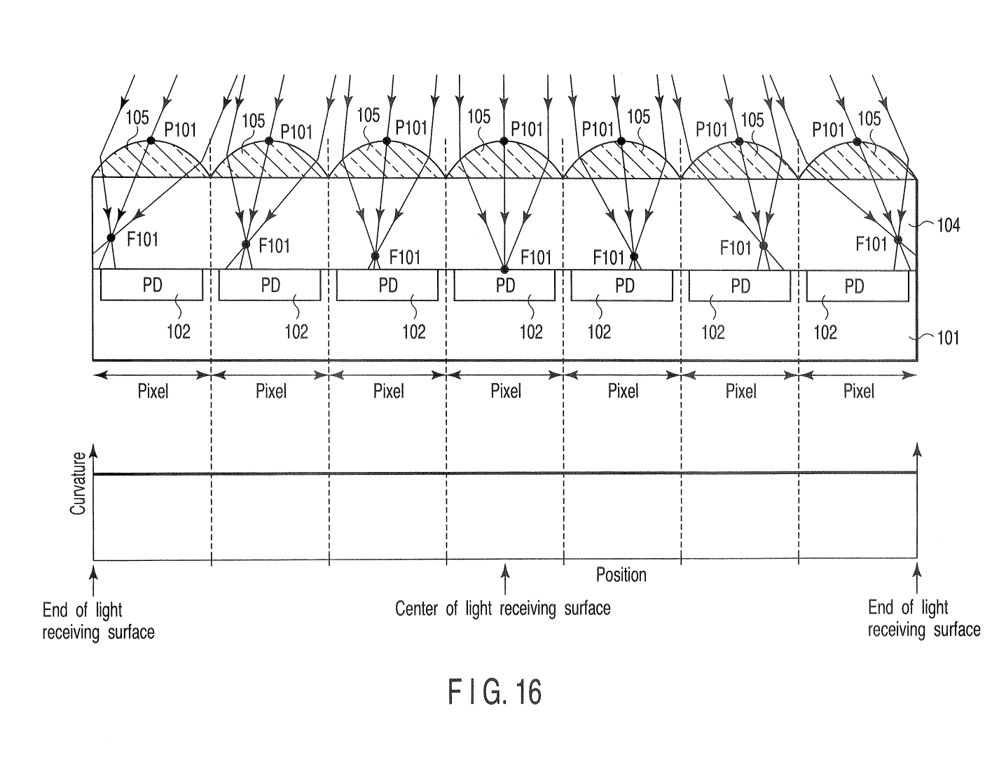

With the configuration in accordance with the present embodiment, incident light efficiently enters the photodiode 29 even at the ends of the surface of the light receiving section 20. This enables the inhibition of a decrease in the photosensitivity of the solid-state image sensor. This effect will be described in connection with the case where the microlens 43 has a fixed curvature in the center and at the ends of the light receiving section. FIG. 16 is a sectional view of the light receiving section 20.

As shown in FIG. 16, microlenses 105 have a fixed curvature throughout the light receiving section 20. Accordingly, the microlens 105 has the same focal distance (the distance from the surface to focus F101 of the microlens 105) both in the center and at the ends of the light receiving section. Incident light is perpendicularly incident on the microlens 105 in the center of the light receiving section. However, incident light is obliquely incident on the microlens 105 at the ends of the light receiving section. Then, for example, if the focal distance of the microlens 105 is designed so that an image is formed on the surface of the photodiode 102 in the center of the light receiving section, the distance from the surface of the photodiode 102 to the focus F101 increases consistently with the distance from the center of the light receiving section. This prevents part of the incident light from entering the photodiode 102, reducing the photosensitivity of the solid-state image sensor.

In contrast, in the present embodiment, the curvature of the microlens 43 decreases consistently with increasing distance from the center of the light receiving section 20 as shown in FIG. 15. In other words, the focal distance (the distance from the microlens 43 to the focus F4) of the microlens 43 increases in keeping with the distance from the center of the light receiving section 20. Thus, the focus F4 of the microlens 43 is located on the surface of the photodiode 29 even at the ends of the light receiving section 20. Consequently, incident light efficiently enter the photodiode 29, allowing the photosensitivity of the solid-state image sensor to be improved.

### Seventh Embodiment

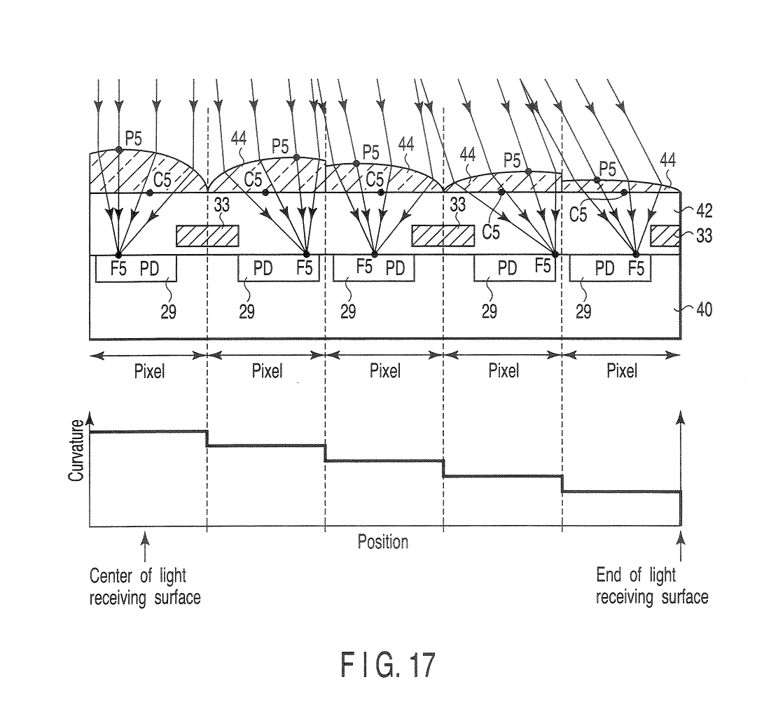

Now, a solid-state image sensor in accordance with a seventh embodiment of the present invention will be described. The present embodiment corresponds to the combination of the first to fifth embodiments with the sixth embodiment. FIG. 17 is a sectional view of partial area of the light receiving section 20 of the solid-state image sensor. Also in FIG. 17, for simplification, the illustration of some of the gate electrodes 33 and gate wiring layers 6 is omitted.

As shown in FIG. 17, microlenses 44 in the solid-state image sensor in accordance with the present embodiment have different fixed curvatures. The curvature of the microlens 44 decreases from the center toward the ends of the light receiving section 20. As described in the first to fifth embodiments, the position of top P5 of the microlens 44 is different from that of center C5 of the bottom surface in the horizontal direction.

The configuration in accordance with the present embodiment exerts the effects (1) and (2), described in the first to third embodiments, and the effect (3), described in the sixth embodiment.

As described above, in the solid-state image sensor in accordance with the first to fifth embodiments of the present invention, the incident surfaces of the microlenses, which condense incident light on the photodiodes, have a fixed e curvature. Further, the top of each microlens is away from the center of its bottom surface in the horizontal direction. Consequently, the microlens has a focus at a position away from the center of the corresponding pixel. This makes it possible to prevent incident light from being blocked by the gate electrode or the like. A decrease in the photosensitivity of the solid-state image sensor can thus be inhibited.

Further, the solid-state image sensor in accordance with the sixth and seventh embodiments, the curvature of the microlens is larger in the center of the light receiving section and is smaller at the ends. This allows light to efficiently enter the photodiode even at the ends of the light receiving section, where light is obliquely incident on the microlens.

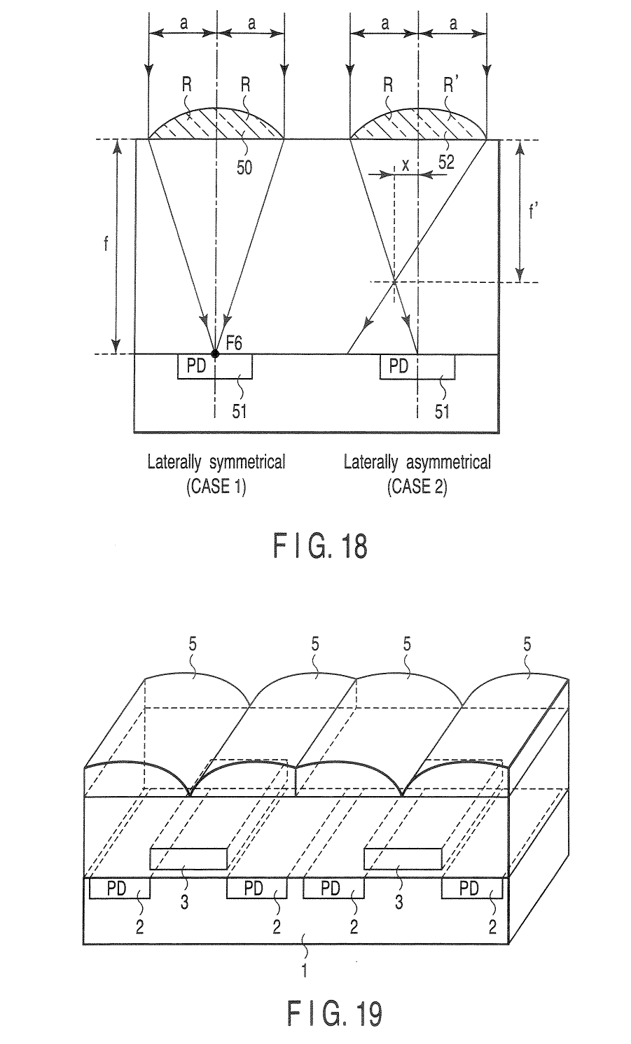

In the first to seventh embodiments, the term “fixed” curvature accepts such errors as described below. FIG. 18 is a sectional view of the microlenses, showing how incident light is condensed. First, when a microlens 50 is laterally symmetrical (curvature R) with respect to an optical axis OP1 (CASE 1), the focal distances on the right and left sides of the microlens 50 are both f. Accordingly, given the ideal optical system, beams emitted from the microlens 50 to a photodiode 51 intersect at one point. This point corresponds to a focus F6.

However, it is assumed that the microlens is laterally asymmetrical with respect to the optical axis OP1 and that the curvature and focal distance on the left side of the optical axis OP1 are R and f, respectively, whereas the curvature and focal distance on the right side of the optical axis OP1 are R′ and f′, respectively (CASE2). Then, the beams condensed by the microlens 52 do not interest at one point. Thus, in an area where light condensed at the rightmost position of the microlens 52 and light condensed at the leftmost position of the microlens 52 cross, the beam has a width x expressed by:
x=a·|f−f′|/(f+f′)
where a is the radius of the microlens 52. Since light is an electromagnetic wave, it originally has a spread equal to its wavelength. Accordingly, no practical problem occurs provided that the width x is equal to the wavelength λ. In particular, with a visual light sensor, x shorter than 555 nm reduces the adverse effect of the difference in the curvature of the microlens 50 between its right and left sides; at a wavelength of 555 nm, human beings have the highest visibility. That is, the following equation is desirably satisfied.
x=a·|f−f′|/(f+f′)<λ(=555 nm)

Of course, λ can be appropriately selected by the solid-state image sensor. The relation between the radius of curvature and the focus of the microlens 52 is expressed by:
(1/f)=(nL−1)/R
where nL is the refractive index of the microlens 52. Consequently, the following equation is derived.
x=a·|R−R′|/(R+R′)<λ(=555 nm)
The above range corresponds to the “fixed curvature” in the above embodiments.

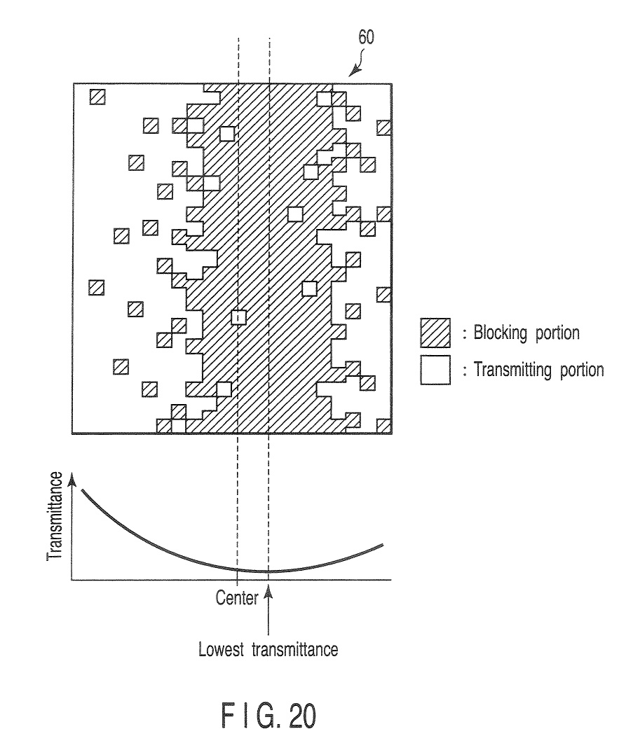

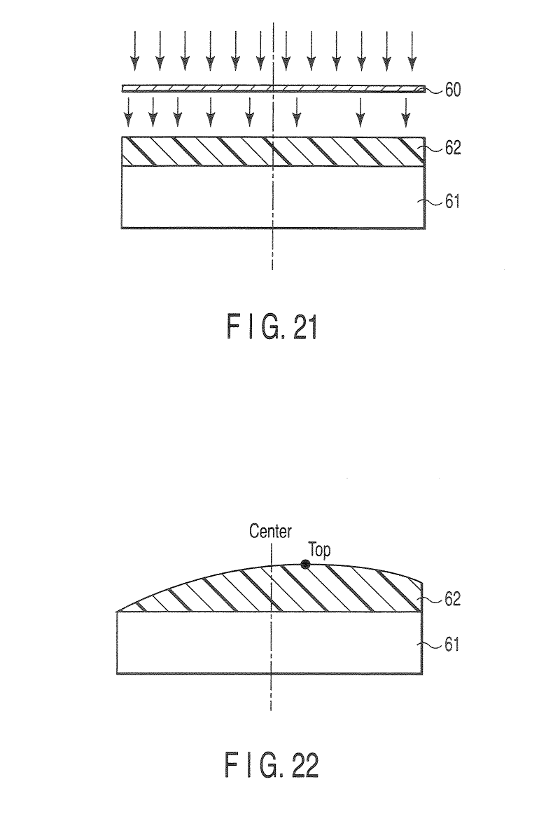

The microlens may be a cylindrical lens 5 such as the one shown in FIG. 19. Further, the microlenses in accordance with the above embodiments can be produced using a photomask shown in FIG. 20. FIG. 20 shows a plan view of the photomask as well as transmittance. In the figure, a shaded portion is an area where light is blocked, and in an outline area, light is transmitted. As shown in the figure, the photomask 60 is designed so that its transmittance is high at its opposite ends and lowest at a position a given distance away from the center. With reference to FIGS. 21 and 22, a method for manufacturing a microlens using the photomask 60 will be described. FIGS. 21 and 22 are sectional views sequentially showing a process of producing a microlens in accordance with the present embodiment.

First, as shown in FIG. 21, a photoresist 62 is coated on an insulating film 61. The photoresist 62 is exposed by a photolithography technique using the photomask 60. This causes the photoresist 62 to be removed significantly in a part corresponding to the area of the photomask 60 having a higher transmittance and virtually unremoved in a part corresponding to the area of the photomask 60 having a lower transmittance. That is, as shown in FIG. 22, the photoresist 62 is processed into a spherical shape having a top in an area a given width away from the center of the photomask 60, that is, the center of the resist 62. The spherical resist 62 is used as the microlens described in the above embodiments.

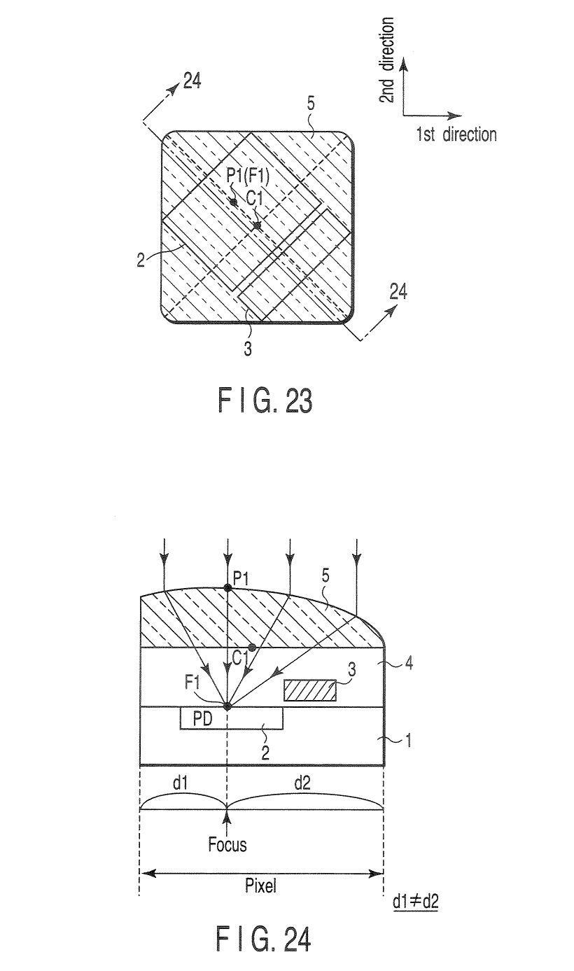

Further, in the description of the above embodiments, the microlens 5 is rectangular, and the gate electrode 3 is placed parallel to one side of the microlens 5. However, the gate electrode 3 may be placed obliquely to one side of the microlens 5. This case will be described with reference to FIGS. 23 and 24. FIG. 23 is a plan view of one pixel. FIG. 24 is a sectional view of the pixel taken along line 24-24 in FIG. 23.

As shown in the figures, the microlens 5 is rectangular and its sides are formed along a first direction or a second direction perpendicular to the first direction. The gate electrode 3 and the photodiode 2 are arranged at 45° to the first and second directions. In this configuration, the position of top P1 of the microlens 5, that is, the position of the focus Fl, is different from that of the center C1 of bottom surface of the microlens 5 in a horizontal plane. More specifically, as shown in the figures, the top P1 (focus F1) is located opposite the gate electrode 3 across the center C1 in the direction in which the photodiode 2 and the gate electrode 3 are arranged.

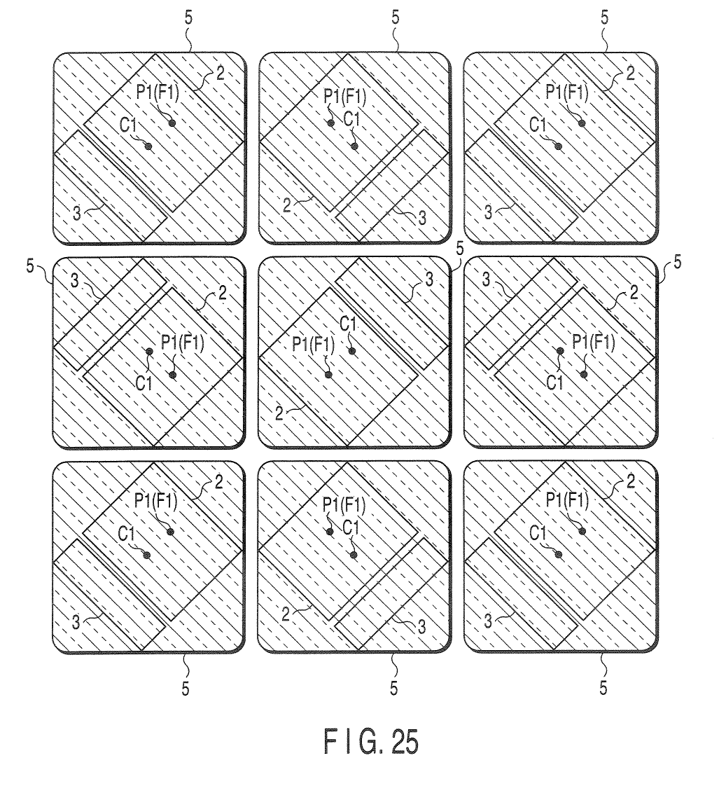

FIG. 25 is a plan view showing the configuration of the light receiving section 20 in the solid-state image sensor in which a plurality of the pixels configured as described above are arranged. As shown in the figure, the configuration described in the above embodiments and shown in FIGS. 9, 12, and 14 may be replaced with the one shown in FIG. 25.

The third to seventh embodiments can also be applied to a configuration having metal wiring layers and gates as is the case with the second embodiment or having metal wiring layers but not gates. If the configuration has metal wiring layers and gates, incident light is more likely to be blocked because the metal wiring layers are normally provided above the gates. Therefore, the curvature of the microlens is desirably designed giving more considerations to the metal wiring layers than to the gates.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A solid-state image sensor comprising:
pixels on a semiconductor substrate, each of the pixels including a photodetecting section which photoelectrically converts incident light; and
lenses which condense the incident light on the photodetecting section, the lenses having a fixed curvature on an incident surface for the incident light, a top of the incident surface of each of the lenses being at a position different from that of a center of a bottom surface of each of the lenses in a direction horizontal to the bottom surface.

2. The sensor according to claim 1, wherein each of the pixels further includes a switch element provided adjacent to the photodetecting section to read charges provided by the photodetecting section by photoelectrically converting the incident light,
the switch elements in adjacent pixels are adjacent each other, and
each of the lenses is provided for each of the pixels, and the top of each of the lenses is located opposite the switch element across the center of each of the lenses in a direction in which the photodetecting section and the switch element are arranged.

3. The sensor according to claim 1, further comprising metal wiring layers provided between the semiconductor substrate and the lenses,
wherein each of the lenses is provided for the corresponding one of the pixels, and the top of each of the lenses is located, in a direction horizontal to a surface of the semiconductor substrate, opposite one of two of the metal wiring layers which are opposite each other across a perpendicular to the semiconductor substrate surface which contains a center of surface of the photodetecting section, the one metal wiring layer being closer to the perpendicular.

4. The sensor according to claim 1, wherein the lenses located in a center of a light receiving surface on which the pixels are two-dimensionally arranged have a larger curvature than the lenses located in a periphery of the light receiving surface.

5. The sensor according to claim 1, wherein the curvature of each lenses satisfies the following relation:
a·|R−R′|/(R+R′)<555 nm
where a is the radius of each of the lens,
R is the curvature of one of two sides of the incident surface which are opposite each other across a perpendicular passing through the center of bottom surface of each of the lenses, and
R″ is the curvature of the other of the two side of the incident surface which are opposite each other across the perpendicular passing through the center of bottom surface of each of the lenses.

6. A solid-state image sensor comprising:
pixels on a semiconductor substrate, each of the pixels including a photodetecting section which photoelectrically converts incident light;
unit cells each including the pixels and a signal output section which outputs information corresponding to signal charges read from the pixels;
a light receiving section in which the unit cells are arranged;
lenses formed above the light receiving section and each provided for the corresponding one of the pixels to condense the incident light on the photodetecting section of the corresponding pixel, the lenses having a fixed curvature on an incident surface for the incident light, a top of incident surface of each of the lenses being at a position different from that of a center of a bottom surface of each of the lenses in a direction horizontal to the bottom surface.

7. The sensor according to claim 6, wherein each of the unit cells includes two of the pixels and the signal output section shared by the two pixels, and
the signal output section is located in an area between the two pixels included in the same unit cell.

8. The sensor according to claim 6, wherein each of the unit cells includes four of the pixels and the signal output section shared by the four pixels,
the four pixels included in the same unit cell are arranged in a (2×2) matrix, and
the signal output section is located in an area between columns of the pixels in the same unit cell.

9. The sensor according to claim 6, wherein the unit cells each include two of the pixels which are adjacent to each other in a vertical direction in a surface of the light receiving section and are arranged in a checkered pattern in the light receiving section,
the signal output section extends from an area between the two pixels included in a given unit cell over an area between two unit cells which are adjacent to the given unit cell in a horizontal direction, and
the photodetecting sections each included in one of the pixels in each of two unit cells obliquely adjacent to each other are arranged on the same horizontal line.

10. The sensor according to claim 6, wherein each of the pixels further includes a switch element provided adjacent to the photodetecting section to read charges provided by the photodetecting section by photoelectrically converting the incident light,
the switch elements in adjacent pixels are adjacent to each other, and
each of the lenses is provided for each of the pixels, and the top of each of the lenses is located opposite the switch element across the center of each of the lenses in a direction in which the photodetecting section and the switch element are arranged.

11. The sensor according to claim 6, further comprising metal wiring layers provided between the semiconductor substrate and the lenses,
wherein the top of each of the lenses is located, in a direction horizontal to a surface of the semiconductor substrate, opposite one of two of the metal wiring layers which are opposite each other across a perpendicular to the semiconductor substrate surface which contains a center of surface of the photodetecting section, the one metal wiring layer being closer to the perpendicular.

12. The sensor according to claim 6, wherein the lenses located in a center of a light receiving surface on which the pixels are two-dimensionally arranged have a larger curvature than the lenses located in a periphery of the light receiving surface.

13. The sensor according to claim 6, wherein the curvature of each lens satisfies the following relation:
a·|R−R′|/(R+R′)<555 nm
where a is the radius of each of the lenses,
R is the curvature of one of two sides of the incident surface which are opposite each other across a perpendicular passing through the center of bottom surface of each of the lenses, and
R′ is the curvature of the other of the two side of the incident surface which are opposite each other across the perpendicular passing through the center of bottom surface of each of the lenses.

14. A solid-state image sensor comprising:
pixels on a semiconductor substrate, each of the pixels including a photodetecting section which photoelectrically converts incident light;
a light receiving surface on which the pixels are two-dimensionally arranged; and
lenses provided above the light receiving surface to condense the incident light on the photodetecting section, the lenses having a fixed curvature on an incident surface for the incident light, a lens located in a center of the light receiving surface having a larger curvature than a lens located in a periphery of the light receiving surface.

15. The sensor according to claim 14, wherein a top of incident surface of each of the lenses is at a position different from that of a center of a bottom surface of each of the lenses in a direction horizontal to the bottom surface.

16. The sensor according to claim 15, wherein each of the pixels further includes a switch element provided adjacent to the photodetecting section to read charges provided by the photodetecting section by photoelectrically converting the incident light,
the switch elements in adjacent pixels are adjacent to each other, and
each of the lenses is provided for each of the pixels, and the top of the lenses is located opposite the switch element across the center of each of the lenses in a direction in which the photodetecting section and the switch element are arranged.

17. The sensor according to claim 15, further comprising metal wiring layers provided between the semiconductor substrate and the lenses,
wherein each of the lenses is provided for the corresponding one of the pixels, and the top of each of the lenses is located, in a direction horizontal to a surface of the semiconductor substrate, opposite one of two of the metal wiring layers which are opposite each other across a perpendicular to the semiconductor substrate surface which contains a center of surface of the photodetecting section, the one metal wiring layer being closer to the perpendicular.

18. The sensor according to claim 15, wherein the curvature of each of the lenses satisfies the following relation:
a·|R−R′|/(R+R′)<555 nm
where a is the radius of each of the lenses,
R is the curvature of one of two sides of the incident surface which are opposite each other across a perpendicular passing through the center of bottom surface of each of the lenses, and
R′ is the curvature of the other of the two side of the incident surface which are opposite each other across the perpendicular passing through the center of bottom surface of each of the lenses.

19. The sensor according to claim 2, wherein each of the lenses is rectangular, and
the switch element includes a MOS transistor which has a gate electrode placed obliquely to one side of the lens.

20. The sensor according to claim 19, wherein the gate electrode id arranged at 45° to the one side of the lens in a horizontal plane.
